(19) United States
(12) Patent Application Publication
(10) Pub. No.: US 2019/0252571 A1
(43) Pub. Date: Aug. 15, 2019

(54) METHOD OF EPITAXIAL GROWTH OF A MATERIAL INTERFACE BETWEEN GROUP III-V MATERIALS AND SILICON WAFERS PROVIDING COUNTERBALANCING OF RESIDUAL STRAINS

(71) Applicant: Integrated Solar, Trondheim (NO)

(72) Inventors: Renato BUGGE, Trondheim (NO); Geir MYRVÅGNES, Trondheim (NO)

(21) Appl. No.: 16/397,572

(22) Filed: Apr. 29, 2019

Related U.S. Application Data
(63) Continuation-in-part of application No. 15/536,834, filed on Jun. 16, 2017.

(30) Foreign Application Priority Data
Dec. 23, 2014 (EP) 14200021.5

(51) Int. Cl. H01L 31/18; H01L 31/0725; H01L 31/074

(52) U.S. Cl. CPC H01L 31/1852; H01L 31/074; H01L 31/0725; H01L 31/1844

(57) ABSTRACT

The present invention relates to a method of manufacturing semiconductor materials comprising interface layers of group III-V materials in combination with Si substrates. Especially the present invention is related to a method of manufacturing semiconductor materials comprising GaAs in combination with Si(111) substrates, wherein residual strain due to different thermal expansion coefficient of respective materials is counteracted by introducing added layer(s) compensating the residual strain.

### FIELD OF THE INVENTION

The present invention relates to a method of manufacturing semiconductor materials comprising interface layers between III-V materials and Si substrates, and especially to a method of manufacturing materials comprising GaAs in combination with Si(111) substrates providing counterbalancing of residual tensile strains left in the materials after epitaxial growth of the material combination.

### BACKGROUND OF THE INVENTION

In the field of semiconductor material science, gallium arsenide (GaAs) is known to have many desirable properties as a foundation for semiconductors. The mobility and other physical properties of this material increase the speed of semiconductor devices made from this material significantly compared with the more traditional semiconductor materials like silicon (Si). However, Si is a much cheaper material than GaAs. Therefore, manufacturing a semiconductor material combination, i.e. a semiconductor device, comprising GaAs in combination with a Si wafer support is a desirable material combination providing beneficial semiconductor properties at beneficial cost. Manufacturing transistors would then provide high frequency devices combined with known Si integrated circuit manufacturing technologies, solar cells would have higher efficiency at a lower price and manufacturing of lasers is possible with larger scale production with cheaper substrates. Further, integration of optical devices on a same chip comprising integrated electronic circuits will be facilitated.

These preferable material properties and combinations have been known for a long time in the prior art. However, epitaxial growth of high quality mono-crystalline GaAs in combination with mono-crystalline silicon is not trivial due to the large lattice mismatch of the two materials. When combining these materials, as known to a person skilled in the art, the lattice mismatch may lead to stacking of faults, denoted threading dislocations that may ruin the physical properties necessary for making semiconductor devices that fulfils the desired quality requirements. The threading dislocations appear for example as known in prior art in an epitaxial growth of a GaAs layer on top of a nucleation layer on a Si wafer.

The threading dislocations will have a certain orientation relative to the epitaxial growth direction, for example almost parallel or within a limited range of angles from the growth direction. The length of the threading dislocations may be shorter than the end thickness of the applied GaAs layer, but thickness of layers in semiconductor devices contributes significantly to what kind of physical properties the material will provide as a basis for a semiconductor device, for example how transparent an optical device can be. Even though the length of the threading dislocations may be limited, the physical property of the interface between the different materials still needs to be controllable, especially when thin layers comprising GaAs is applied, which is a beneficial cost saving parameter.

There are further problems related to epitaxial growth of materials. The growth process in itself can lead to unwanted defects in the resulting crystal structure. For example, the growth process may include using a certain high temperature range above a certain temperature providing good crystal structures and avoiding amorphous states. However, when materials cools down after processing at high temperatures, reorientation of material structures may occur and provide material defects that may influence for example electrical and/or optical characteristics of a device manufactured out of the material.

One important property being dependent on parameters of the epitaxial growth process is differences in height over a surface after the epitaxial growth of a layer. When applying an additional layer on a finished material layer, any height differences will propagate into the added layer and thereby probably induce further defects in the combined material structure. This parameter is especially important when adding a first layer, for example on top of a nucleation layer, since homogeneity of the crystal structure in this layer directly improves electrical and optical properties of the interface. Therefore, having surfaces with less height differences is an important parameter.

Another important factor is the possible different thermal expansion coefficients of respective materials used in epitaxial growth processes. Yasumasa Okada et al disclosed in the article “Precise determination of lattice parameter and thermal expansion coefficient of silicon between 300 and 1500 K”, J. Appl. Phys. 56(2), 15 Jul. 1984 the problem of different thermal expansion coefficients at high temperatures. They investigated thin silicon-oxide layers on silicon often providing strain in the materials near the interface between the materials. In semiconductor solar cell technology, it is beneficial to have larger areas of the solar cell structures to increase the efficiency of cells. The possible induced strains in material layers can result in a bending of the cell surface, which influence the efficiency of the large solar cell surface. In fact, in the solar cell industry it has been investigations of using group III-V materials in combination with Si wafers. However, the differences in thermal expansion coefficients and the large lattice mismatch between these materials is identified as a reason for not using group III-V materials on Si substrates in solar cells.

However, there is progress in the prior art with respect to solve and understand the physics of the problems of combining silicon wafers and group III-V materials. For example, threading dislocations as discussed above has been tried to be solved in the prior art because of the significant benefits of using group III-V materials in combination with Si wafers, for example in solar cells. In prior art there are known some examples of experimental processes trying to achieve a combination of for example GaAs with non III-V materials like Si substrates that has used relative thick buffer layers and/or strained-layer super lattices to reduce defect densities. For example, an interface layer, super-lattice and/or buffer layer with a thickness of 1000 Å or more is used in experimental methods. This is an essential problem, since such a dimension of a layer with no other function than being a buffer will create extra material costs and production time in addition to being detrimental to device performance. For example, in a solar cell application, this layer will contribute with additional impedance and the layer may absorb light without generating electricity.

M. Yamaguchi, M. Tachikawa, Y. Itoh, M. Sugo, S. Kondo: “Thermal annealing effects of defect reduction in GaAs on Si substrates.”, Journal of Applied Physics, Vol. 68, pp. 4518-4522 (1990) shows that thermal annealing can be used to reduce dislocations in GaAs grown directly on (100) Si substrates. Their GaAs layers exhibit a dislocation density at or above 10⁶ cm⁻² prior to annealing. Using several annealing cycles they achieved dislocation densities as low as 3.10⁶ cm⁻², Yamaguchi et al. also shows a dependency between grown thicknesses and number of dislocations, and that the found dislocation density differs when using different examination techniques (EPD (Etch Pit Density) and TEM (Transmission Electron Microscopy)). The lowest number of dislocations was reported for the specimens at 3500 nm of GaAs on Si after four thermal annealing cycles to 900° C.

Another improved method of manufacturing III-V materials in combination with non group III-V materials providing low levels of threading dislocation faults is disclosed in the EP 2748828 application by the same inventors of the present invention.

M. J. Yang et al (1998) demonstrated theoretically how AlGaAs in combination with Si based double junction solar cells could provide high efficiency if the number of threading dislocations in the AlGaAs light absorption layer was reduced. The theoretical value was 31% to 40% efficiency with 1 SUN respectively 500 SUN for Al_{0.21}GaAs/Si based solar cells without loss due to reflections.

Masayoshi Ueno et al (1994) has disclosed an AlGaAs based solar cell in combination with a 2 deg miscut Si(100) substrate, which was also a solar cell. The result was a double junction solar cell with AlGaAs and Si as the base material for the two cells. Each of the cells had a p-i-n junction wherein the i-layer could be slightly doped, i.e. not completely intrinsic thereby enhancing charge transport. One could therefore denote the solar cells as p-i-n, p-p-n or p-n-n junctions, but the middle layer functioned in all cases as a light absorption layer. The junction of the AlGaAs and Si cells provided an efficiency of approximately 20% at 1 SOL and was therefore not economically feasible because mono crystalline silicon solar cells can achieve the same efficiency without AlGaAs. The reason for the low efficiency was assumed to be defects in the AlGaAs layer. Such defects will act as short circuits in the absorption layer and much of the power will not be available outside the solar cell. It is therefore important to make solar cells with at least only minor defects in the absorption layer.

K. Takahashi et al (2005) disclosed that Al_{0.36}GaAs solar cell on (100) GaAs substrate had a higher efficiency by using Se instead of Si to n-type doping of (100) AlGaAs layers. The measured efficiency was 16.05% and 28.85% at 1 SUN for respectively a single junction Al_{0.36}GaAs and double junction Al_{0.36}GaAs/GaAs solar cell.

P. P. Gonzalez-Borrero et al (2001) disclosed that (111) GaAs type of material may be used with epitaxial growth of both n-type and p-type Si doping by only adjusting the V/III flux ratio during the growth process in a MBE machine.

O. Morohara et al (2013) disclosed epitaxial growth of GaAs in combination with Si(111) under Sb flux and achieved a reduction in roughness and defect density at the surface of the material.

Thermal induced stress during high temperature in an epitaxial growth process will be reduced during cooling of the materials after the growth process is finished. A person skilled in the art know that the forces induced in the crystal due to differences in thermal expansion coefficients will be reduced through a process wherein the forces do a work on the crystal structure often resulting in respective crystal defects. However, quite often there is residual stress remaining that for example can bend a larger surface of a solar cell. Such problems may also be a problem when manufacturing MEMS (Micro Electronic Mechanical Systems).

Further, a process and solution to the problem with thermal expansion coefficients cannot be detrimental to the other factors that need to be addressed when manufacturing group III-V materials in combination with Si materials, i.e. threading dislocation density and height differences, for example. On the contrary, it would be beneficial to provide a method and solution of the problem with different thermal expansion coefficients and at the same time achieve lower threading dislocation density and height differences on surfaces of manufactured material samples.

Hence, an improved method of manufacturing group III-V materials in combination with Si substrates is advantageous.

### OBJECT OF THE INVENTION

In particular, it may be seen as an object of the present invention to provide a material combination of layers comprising materials from group III-V material on a non-group III-V material substrate,
providing less dislocation faults and at the same time counteracting any effects of residual strain of the material combination by
adding at least one layer providing compressive strain at the growth temperature in an epitaxial growth process.

It is a further object of the present invention to provide an alternative to the prior art.

### SUMMARY OF THE INVENTION

Thus, the above described object and several other objects are intended to be obtained in a first aspect of the invention by providing a method of counteracting residual strain in semiconductor materials comprising group III-V materials in layers deposited in an epitaxial growth process on a Si(111) wafer, the method comprises steps of:

using an arsenic source during the epitaxial growth process, and

adding a step in the epitaxial growth process constituting a first layer comprising a group III-V material combination providing a specific first lattice constant, followed by adding a further step in the epitaxial growth process constituting a second layer comprising a group III-V material combination providing a specific second lattice constant,

wherein the second lattice constant is less than the first lattice constant, wherein the arsenic concentration varies with a concentration increase of more than 5 at % from the start of growing the first layer to the end of growing the second layer.

A further aspect of the invention is to provide solar cell comprising a first material layer and a second material layer according to the invention.

The individual aspects and/or examples of embodiments of the present invention may each be combined with any of the other aspects and/or examples of embodiments. These and other aspects of the invention will be apparent from the following description with reference to the described embodiments.

### BRIEF DESCRIPTION OF THE FIGURES

The method of epitaxial growth of III/V materials on non III/V materials providing a balancing out of bending forces in finished material samples according to the present invention will now be described in more detail with reference to the accompanying figures. The figures illustrate examples of embodiments of the present invention and are not to be construed as being limited to other possible embodiments falling within the scope of the attached claim set.

FIG. 1 discloses a drawing of a TEM picture of a GaAs/Si interface according to the present invention.

FIG. 1a is depicts the image being basis for the drawing in FIG. 1.

FIG. 2 discloses a drawing of a TEM picture of some material defects after epitaxial growth.

FIG. 2a depicts the image being the basis for the drawing in FIG. 2.

FIG. 3 illustrates an example of embodiment of the present invention.

FIG. 4 illustrates an example of embodiment of the present invention.

FIG. 5 illustrates an example of embodiment of the present invention.

FIG. 6 illustrates an example of embodiment of the present invention.

FIG. 7 depicts a drawing of an EBIC image of a surface of a material sample.

FIG. 7a discloses the image being basis for the drawing in FIG. 5.

FIG. 8 discloses a SEM image of anti domain like defects in a GaAs material sample.

FIG. 8a depicts the image being basis for the drawing in FIG. 6.

FIG. 9 discloses a SEM image of another example of embodiment of the present invention.

FIG. 9a depicts the image being basis for the drawing in FIG. 7.

FIG. 10 discloses a drawing of a Dark Field TEM cross section image from the sample in FIG. 7 and FIG. 7a.

FIG. 10a depicts the image being basis for the drawing in FIG. 8.

FIG. 11 depict a drawing of a high angle annular Dark Field STEM cross section image from one of the leftmost indentations in FIG. 7 and FIG. 7a.

FIG. 11a discloses the image being basis for the drawing in FIG. 9.

FIG. 12 discloses a drawing of possible effects of annealing to room temperature of a material sample.

FIG. 12a depicts the image being basis for the drawing in FIG. 10.

FIG. 13 illustrates a drawing of a dark TEM cross sectional view of the example depicted in FIG. 10 and FIG. 10a.

FIG. 13a illustrates the image being basis for the drawing in FIG. 11.

### DETAILED DESCRIPTION OF AN EMBODIMENT OF THE PRESENT INVENTION

Although the present invention has been described in connection with the specified embodiments, it should not be construed as being in any way limited to the presented examples. The scope of the present invention is to be interpreted in the light of the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

Strain induced at high temperatures in the epitaxial growth process, that is a result of mismatch of thermal expansion coefficients of different materials in respective material layers, will result in forces acting on the crystal being the result of the epitaxial growth process when cooled down to room temperature. The work of the forces do work on the crystal structure resulting in crystal defects. In this process, the strain is reduced. However, respective bindings of the crystal structure in itself may counteract the work of the forces which usually will result in a residual strain in the material combination when reaching room temperature.

There are different defects that might appear due to the work of the forces mentioned above.

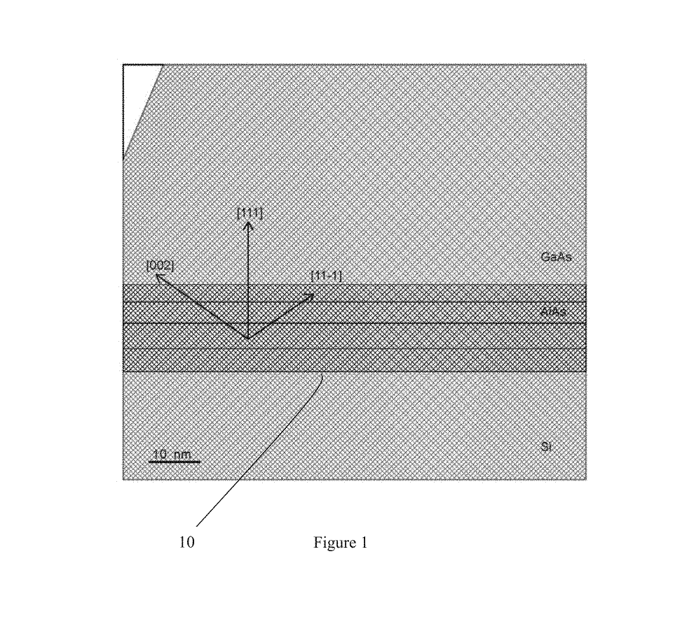

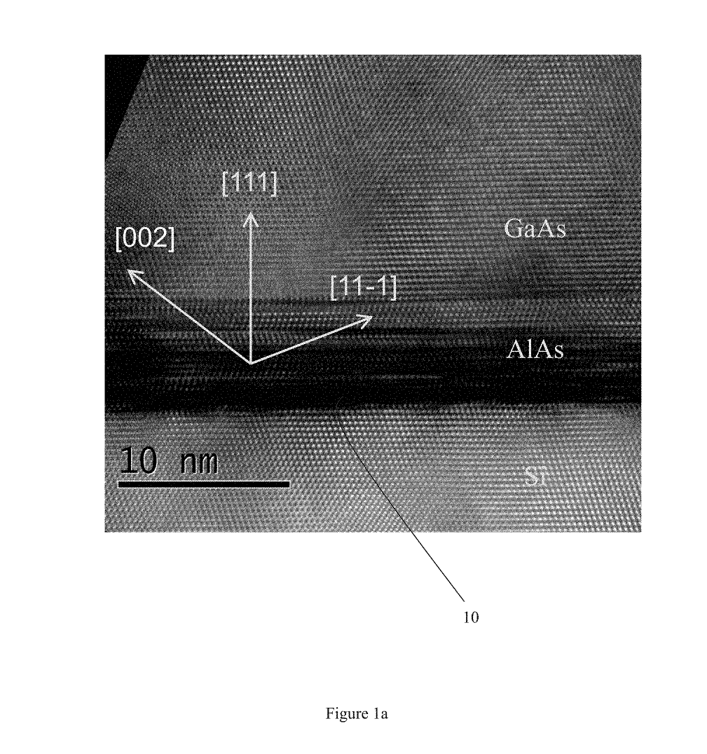

FIG. 1 and FIG. 1a illustrate an example of growing GaAs on Si(111) with a AlAs nucleation layer in between on top of the Si(111) substrate. Similar effects as those identified in FIG. 1 and FIG. 1a and the other figures having a nucleation layer is also present with other nucleation layer combinations. For example, a nucleation layer constituted by for example AlAsSb, InAsSb, AlInAsSb, display the same structures and effects as documented in the respective Figures.

Further, FIG. 1a and FIG. 1 illustrates a layer of GaAs. Similar effects illustrated in FIG. 1 and FIG. 1a and the other figures displaying a GaAs layer have the same structure and effects when GaAs is substituted with GaAsSb.

FIG. 1a is an electron microscope picture (TEM picture) while FIG. 1 is a drawing of the same picture highlighting the structural elements found in the picture in FIG. 1. The growth direction is in the crystallographic plane of [111].

Materials from the group III-V of the periodic system do have a significantly higher thermal expansion coefficient than Silicon. When performing an epitaxial growth processes it is necessary to apply high temperatures (for example it is known to use temperatures of 670° C.) to be able to create good crystal structures and to avoid amorphous states in sections or parts of the material combination.

Therefore, if unstrained group III-V-material is applied on a nucleation layer on a silicon wafer at growth temperature, it will shrink relative to the wafer surface size when everything is cooled down to room temperature. This can cause defects and cracks, as well as bending of the wafer because of the high strain forces involved. The article “Crack formation in GaAs heteroepitaxial films on Si and SiGe virtual substrates”, JOURNAL OF APPLIED PHYSICS VOLUME 93, NUMBER 7 1 Apr. 2003 disclose further details about this problem.

However, there is one interesting aspect of growing GaAs on a nucleation layer on a silicon substrates of Si(111). With reference to FIG. 1 (and FIG. 1a) there are threading dislocations 10 being parallel with the surface of the Si(111) substrate. This is an astonishing effect documented in FIG. 1 (and FIG. 1a) and the threading dislocations are staying in the plane and is not propagating into the GaAs material as known with junctions of group III-V materials on Si(100) (Refer for example EP 2748828). Further, verification of this effect has been done by the inventors and the results are the same. The direction of threading dislocations is parallel with the material surface. Therefore, applying thin GaAs layers on Si(111) will be possible from an electronic/optical point of view.

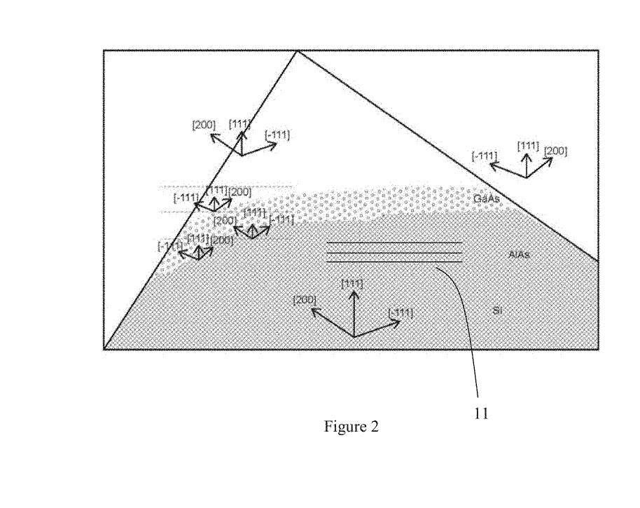

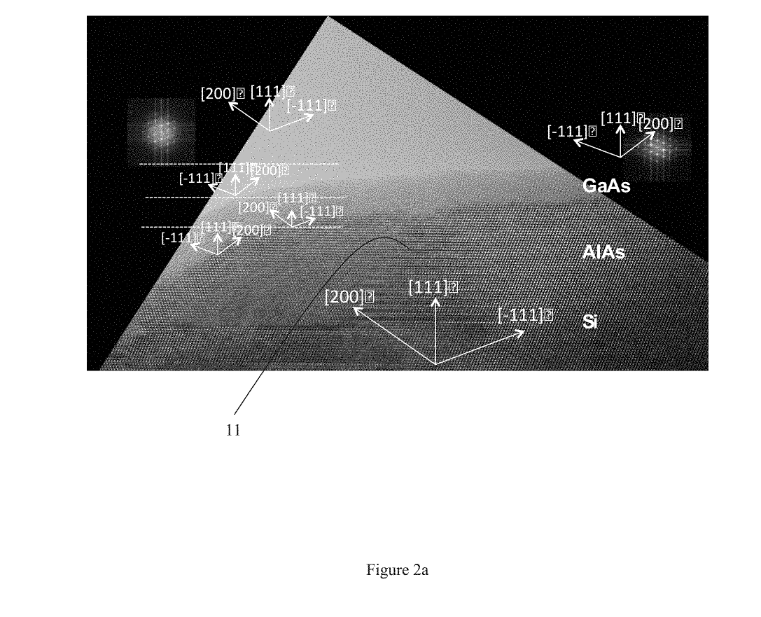

FIG. 2 (and FIG. 2a) disclose a drawing of a cross sectional TEM view of the material sample disclosed in FIG. 1 and FIG. 1a. This image illustrates other types of crystal defects that can arise during the processing of group III-V materials on Si (111). As illustrated with the marking of different crystal orientations in the structure, it is established domains wherein the GaAS growth is resulting in different stacking of crystal orientations. Some places the stacking defects looks more like grain boundaries. However, as indicated by reference numerals 11 in FIG. 2 and FIG. 2a the difference in thermal expansion coefficient and the work done by the corresponding resulting forces results in creation of defect planes in the combined material. The work is resulting in parallel defect planes oriented parallel to the surface of the Si(111) substrate. The work done by the forces creating the defect planes reduces the thermal induced strain, but a residual strain may remain as discussed above. Therefore, the defects due to the relaxation of strain during the cooling of the material combination do not affect the GaAs layer with respect to electrical/optical properties.

However, bending of the material combination may still be a problem in many applications as discussed above. The bending is typical a problem related to solar cells where layers in material interfaces are made thinner to make the layers cheaper and more transparent to incoming light.

It is known from prior art that there is a correlation or functional relationship between thermal expansion coefficients of crystals and lattice parameters. For example as disclosed in “Precise determination of lattice parameter and thermal expansion coefficient of silicon between 300 and 1500 K”, J. Appl. Phys. 56(2), 15 Jul. 1984 by Yasumasa Okada et al.

An aspect of the present invention is the possibility to modify lattice constants of layers thereby mitigating effects of differences in thermal expansion coefficients.

Therefore, a principle generic method of counteracting residual strain in group III-V materials in a combination with a Si wafer supporting semiconductor layers constituted in an epitaxial growth process, the method comprise steps of: when the semiconductor layers have a thermal expansion coefficient higher than the thermal expansion coefficient of the Si wafer supporting the semiconductor layers, adding a step in the epitaxial growth process providing an additional material layer having an initial lattice constant in the growth direction, followed by adjusting the material or material composition providing decreasing lattice constant in the growth direction, thereby

when the semiconductor layers have a thermal expansion coefficient lower than the thermal expansion coefficient of the Si wafer supporting the semiconductor layers,

adding a step in the epitaxial growth process of providing an additional material layer having an initial lattice constant in the growth direction, followed by adjusting the material or material composition providing an increasing lattice constant in the growth direction, thereby the material combination is subject to an expansive strain at the growth temperature.

The relationship between the lattice constants can be achieved by adding a first layer with a first defined lattice constant adapting to the lattice constant of the layer the first layer is grown on i.e. a nucleation layer, followed by a second layer with a lattice constant that is either higher or lower than the first defined lattice constant.

Further, the adaption of a lattice constant can be achieved by varying the flux of a material substance during the epitaxial growth process. For example, it is known that increasing Sb and/or As content can reduce the lattice constant, and by varying the flux of Sb and/or As during the epitaxial growth process a stack of sublayers with a variation of lattice constants is achieved.

Group III-V materials have a substantial higher thermal expansion coefficient (in the range of 4-8.10-6 K-1) compared to silicon (2,6.10-6 K-1). Therefore, growing group III-V materials on a silicon wafer at high temperature (for example 670° C.) will be compressed more than the silicon wafer when cooled down to room temperature. The III-V material layer will therefore be subject to tensile strain, which may damage the layer by cracking of the layer, or the layer may bend upwards at the edges of the Si wafer etc.

With reference to the generic method discussed above, growth of the group III-V material should be performed with compressive strain at the growth temperature such that when cooled down to room temperature the material combinations have a residual strain close to zero. The compressive strain effect can be achieved by the fact that a layer with a different lattice constant will adapt to another lattice constant of an adjacent layer.

This can be achieved by establishing the growth with a given lattice constant, and then continuing growing with a slightly (or adjusted) lower lattice constant. The following applied material will then adjust itself to the underlying lattice constant and become strained compressive.

An example of adjusting the lattice constant of a group III-V material is by increasing or decreasing the content of for example Sb or As. It is known that adding Sb or As will not alter other features of a semiconductor comprising for example AlGaAsSb.

Therefore, an aspect of the present invention is to provide at least a further layer in the epitaxial growth process being able to counteract resulting remaining effects of residual strain after cooling of the material combination to room temperature. It is further an aspect of the present invention to counteract strain by controlling lattice constants of the combined materials.

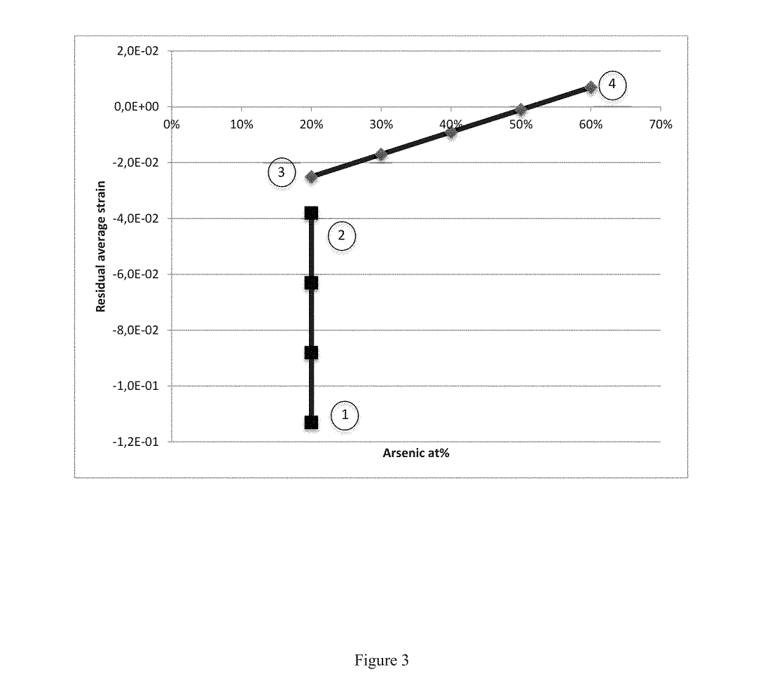

FIG. 3 illustrates an example of embodiment of the present invention illustrating relationship between residual strain versus arsenic (As) content of a first layer. The material combination in this example is constituted by an Si(111) wafer having an AlAs nucleation layer followed by a first layer of Al0.75Ga0.25As0.20Sb0.80. The epitaxial growth process is starting with a residual strain at (1) and growing Al0.75Ga0.25As0.20Sb0.80 on Silicon at 800K, with a number of defect planes reducing the residual strain to a level indicated in (2). Strain is further reduced to (3) by reducing the temperature and can be reduced further by growing a second layer with increased arsenic content over the first layer providing a residual strain as indicated by (4). The As content is given as percentage of group V material in the III-V structure. The calculation assumes 50% contribution to the residual strain from the first and second layer; while the contribution of the defect plane strain is only schematically correct (e.g. it will reduce the strain, but number of defect planes and magnitude is uncertain). A second layer that is thicker than the first layer will increase the residual average strain towards zero for arsenic contents less than illustrated in the FIG. 3. Increasing the Aluminium content to 100 at % and Gallium to 0 at % will change the residual average strain with around 1E-3, thereby the scheme of adjusting the strain will still hold. This is also true when reducing the Aluminum content to 50 at % and increasing Gallium content to 50 at %.

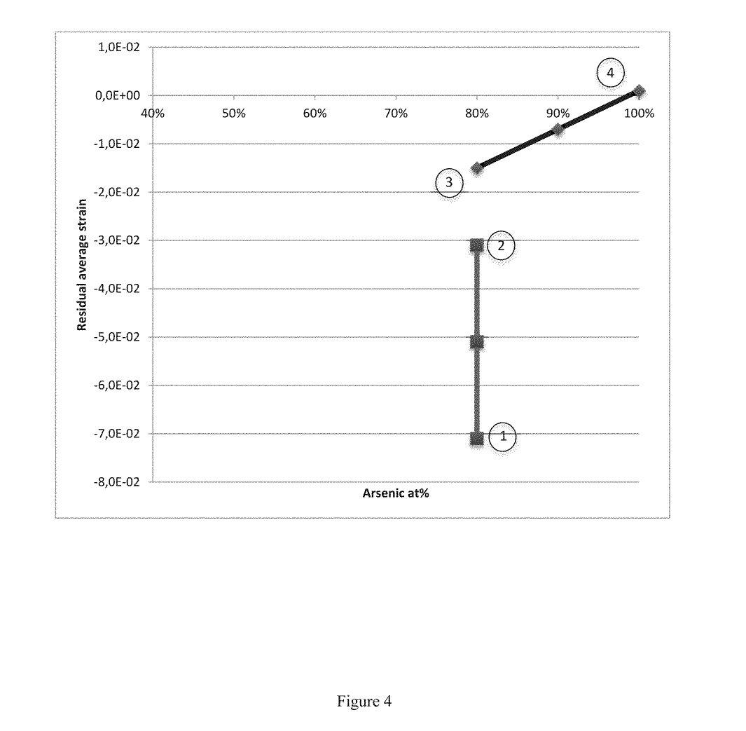

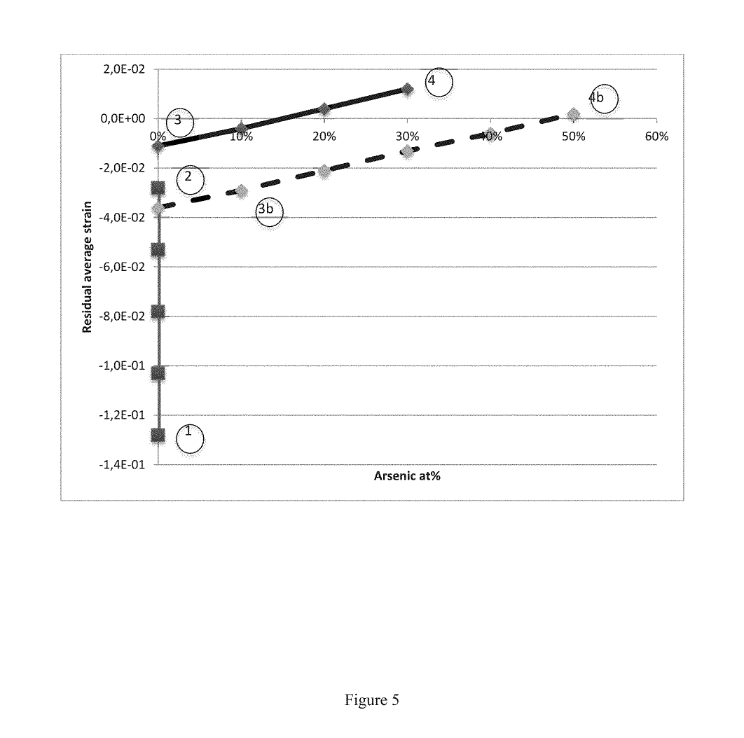

FIG. 4 illustrates another example of embodiment of the present invention. In comparison to FIG. 2, the initial strain at (1), when using higher As concentration in the first layer, is lower. Using 80% As for the first layer also limits the amount of residual strain in (3) that can be compensated for by adding more As in (4). Since more than 100% As as a group V element is impossible, other means of reducing the lattice parameters would have to be used when reducing strain further when 100% is reached. It is possible to add phosphorous (P) to make AlGaAsP with the optional addition of Indium to control the band gap (e.g. AlGaInAsP).

With reference to FIG. 3, changes in the Al/Ga ratio in AlGaAsSb does not constitute a large change in lattice parameter and thus the residual average strain is about the same for all Al/Ga ratios. With the addition of P and/or In this becomes more complex.

FIG. 5 illustrates a further example of embodiment of the present invention, illustrating residual strain of growing Al0.75Ga0.25Sb on Silicon at 800K as a consequence of staring at (1), with a number of defect planes reducing residual strain to (2). Strain is further reduced by reducing temperature to (3) and can be reduced further by growing a second layer with increased arsenic content over the first layer (4). An alternate strain “path” is also shown towards (3b) that ends up around (4b), in which the residual strain in (2) is larger. This can happen if less defect planes are present (the schematics shown reduces the number of strain reduction steps by one). In the case that the strain path along (3b) is real, the amount of Arsenic in the second layer has to be larger to obtain an average strain that is zero (around (4b)).

In comparison with both FIGS. 3 and 4, there is no As in the first layer which translates into a larger initial strain in (1) and thus with more strain reducing defect planes towards (2). This is therefore a solution with less average As in the final product.

With respect to FIG. 3, the ratio of Al/Ga affects the strain to a less extent thereby the method of reducing strain holds for all values of Al/Ga.

In an example of embodiment, the epitaxial growth process comprises an Arsenic cracker that can vary the Arsenic flux from the cracker. In view of the discussion above regarding lattice constant adjustments, the arsenic concentration varies with a concentration increase of more than 5at% from the start of the first layer to the end of the second layer.

In prior art it is known that interaction kinetics plays a role during molecular beam epitaxy (MBE) There are several kinetic steps wherein the incident beams of for example Ga atoms and As₂ and/or As₄ molecules undergo adsorption, desorption, and migration before eventual incorporation into a lattice structure.

The article “Arsenic incorporation in GaAs(001) homoepitaxy revisited” by E. S. TOK et. Al. Surface Science 374 (1997) 397-405 disclose further details.

The inventors has conducted several experiments, for example that an Arsenic BEP (Beam Equivalent Pressure) of 2.0E-6 and Antimony BEP of 1.33E-6 corresponds to an Arsenic content of 14% and Antimony content of 87% at a total growth rate of 0.5 ML/s during growth of Al0.9Ga0.1AsSb.

The conclusion is that the content of Arsen seems to be about 20-30%

It is known in prior art that there is a relationship between combinations of different semiconductor materials versus resulting band gaps and lattice constants. Therefore, as a consequence of adjusting the lattice constant as discussed above, the band gap of a specific material combination may fall outside a desired range.

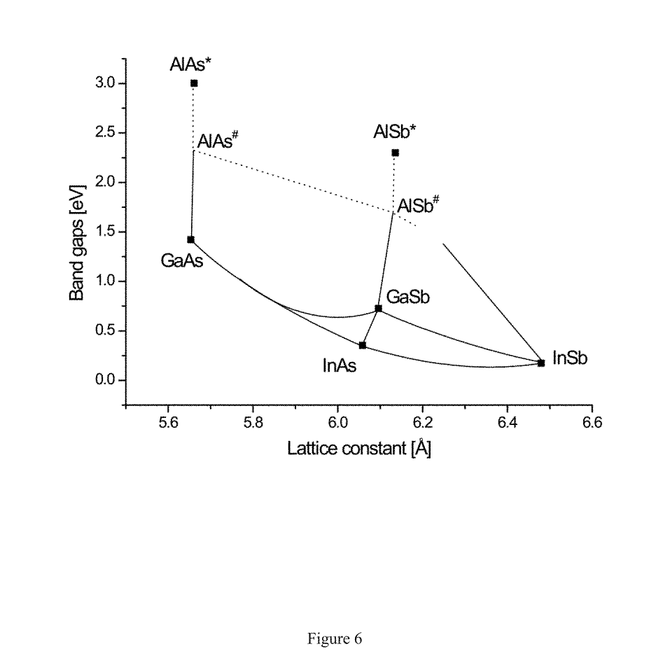

FIG. 6 illustrate a relationship between band gaps versus lattice constants for some examples of binary semiconductors with lines between them that represent ternary composite semiconductors. For example, the line between GaSb and GaAs represent the ternary compound GaAs₁₋ₓSbₓ wherein 0≤x≤1. The solid lines represents areas wherein compounds semiconductor have a direct bandgap that is smaller than the indirect band gap, while the dashed lines represents areas wherein the indirect band gap is smaller than the direct band gap. The graph of FIG. 6 is calculated by the inventor.

Similar tables and graphs can be made by a person skilled in the art for other group III-V materials and material combination with respect to resulting lattice constant or lattice parameters versus band gap. In this manner it is possible to select a combination of lattice constant versus bandgap of at least a first layer and a second layer providing balancing of residual strain based on specific group III-V materials to be used in a specific semiconductor design.

Therefore, in an example of embodiment of the present invention a first layer or nucleation layer can be selected from a non-limiting group of materials constituted by material combinations of:
AlAs,
AlAsₓSb₁₋ₓ, wherein 0<x<1,
InAsₓSb₁₋ₓ, wherein 0<x<1,
AlIn_{y}AsₓSb₁₋ₓ, wherein 0<x<1 and 0<y<1,
   wherein the indexes x, y is selected to provide a specific first lattice constant,

followed by a further second layer selected from the group constituted by
AlAsₓSb₁₋ₓ, wherein 0<x<1,
Al_{y}Ga_{1-y}AsₓSb₁₋ₓ, wherein 0<x<1 and 0<y<1,
AlyGa_{1-y-z}In_{z}AsxSb₁₋ₓ, wherein 0<x<1, and 0<y<1, and 0<z<1, and y+z
   wherein specific values of the indexes x, y, z is selected to provide a second lattice constant, the second lattice constant is to be less than the first lattice constant.

The respective at % content of respective materials can be selected to provide a desired band gap in addition to the specific lattice constants. However, it is important to understand that the relationship between the first lattice constant and the second lattice constant is relative. It is the property of the second lattice constant to be lower than the first lattice constant that is essential such that there will be established a compressive strain at the growth temperature in the interface between the first and second layer. Therefore, the first lattice constant and the second lattice constant can be variable to adapt the semiconductor material to a desired band gap as long as the second lattice constant is lower than the first lattice constant.

For example, the amount of Sb or In or In plus Sb that is used for the lattice constant reduction can be varied within an interval of 2-3 at %. The interval has been suggested by the inventors to be 0-15 at %, preferably between 2-3 at %.

The adjustment of the lattice constant as indicated above can be generalized in the following manner wherein a bottom layer for example is constituted by Si (111), followed by a AlAs₁₋ₓSbₓ nucleation layer, and a top layer comprising for example a material from group III-V of the periodic system combined as a III-V material-As_{1-y}Sbₓ, wherein y<x. The III-V material on the top will conform to the smaller lattice constant, and in that way it will be compressively strained at the growth temperature. This can be done by changing the composition slightly. As an example, adding about 2-3 at % more Sb in an As-based III-V material would increase the lattice constant sufficiently to completely balance out or counteract the bending forces of the material sample. The antimony Sb in the expressions above can be replaced by indium In alone or in a combination of In and Sb.

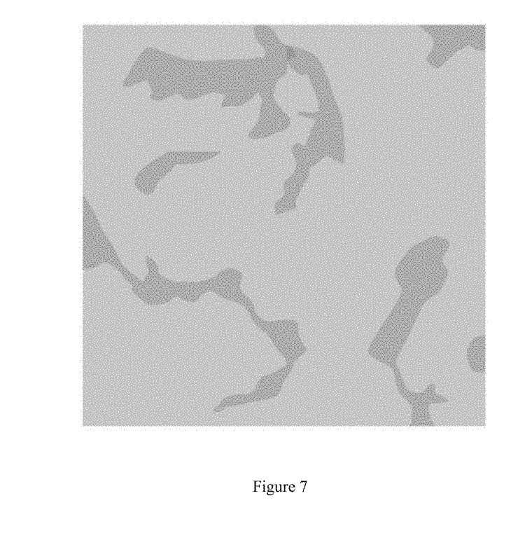

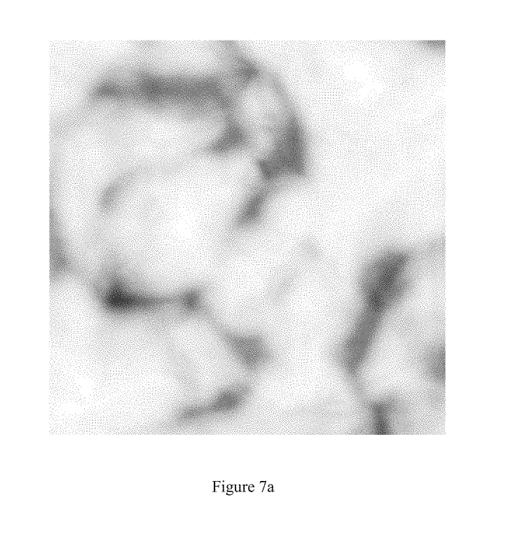

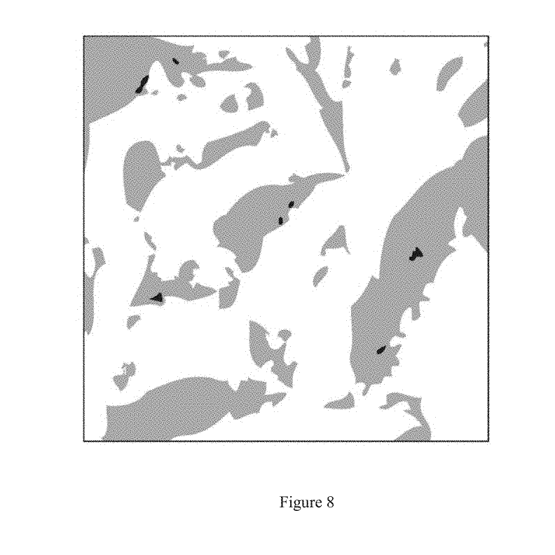

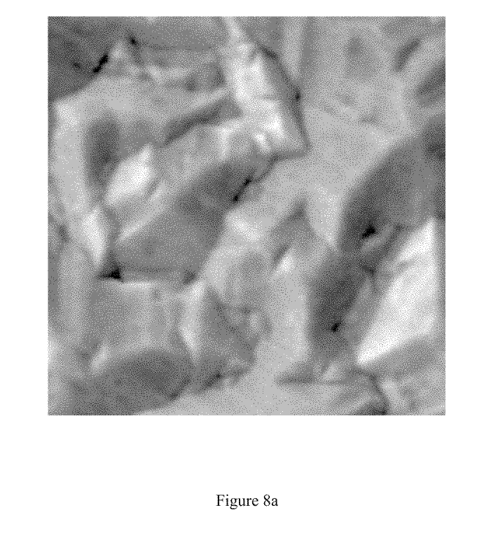

FIG. 7 (and FIG. 7a) illustrates a drawing of an image (FIG. 7a) of EBIC measurements indicating that the material defects provide smaller amounts of recombination of charges as long as the distance to grain boundaries is large enough. FIG. 8 is a drawing of the image in FIG. 8a illustrating anti phase domains providing grain like boundaries in the GaAs material. The light colored areas provide ten times more current than the dark colored areas. The diffusion length has been measured to be 720 nm in average. The size of the area in the images measures 6 μm×6 μm.

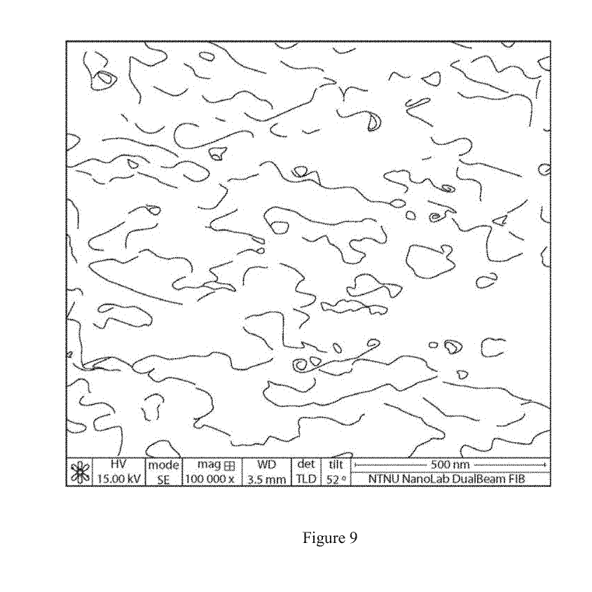

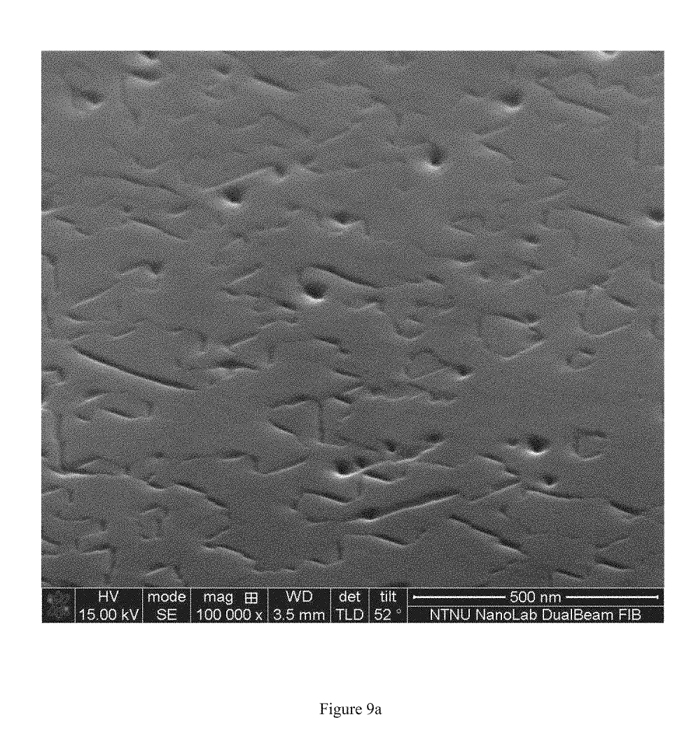

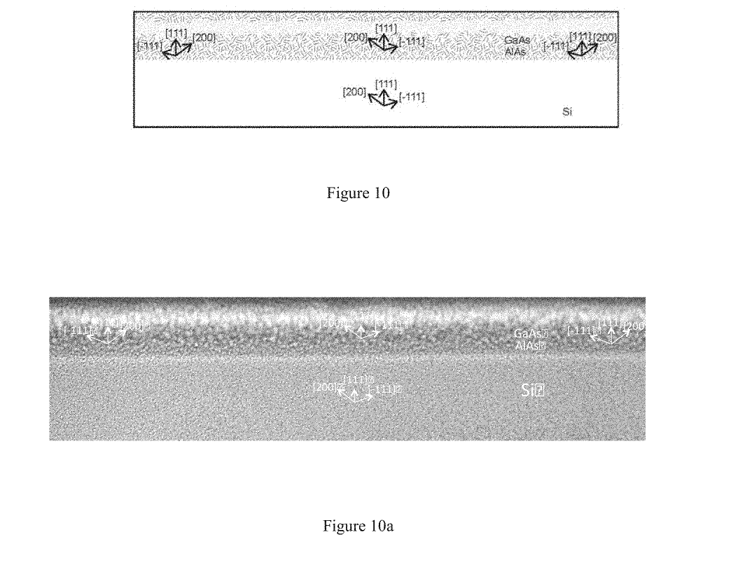

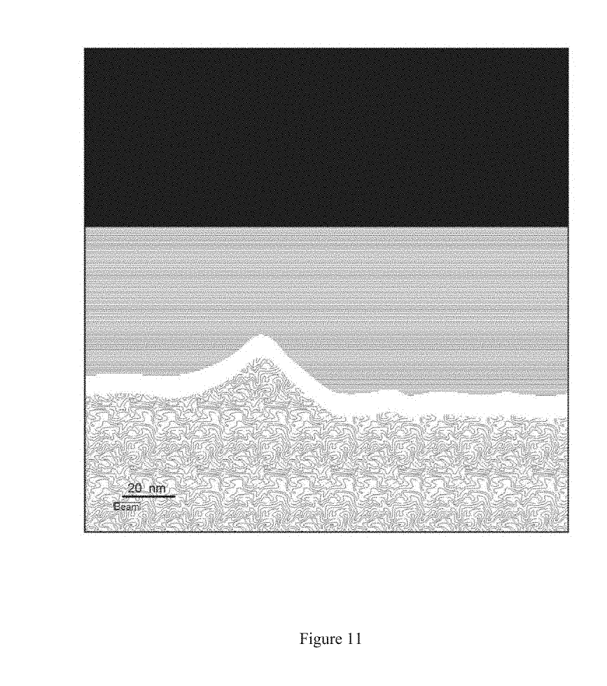

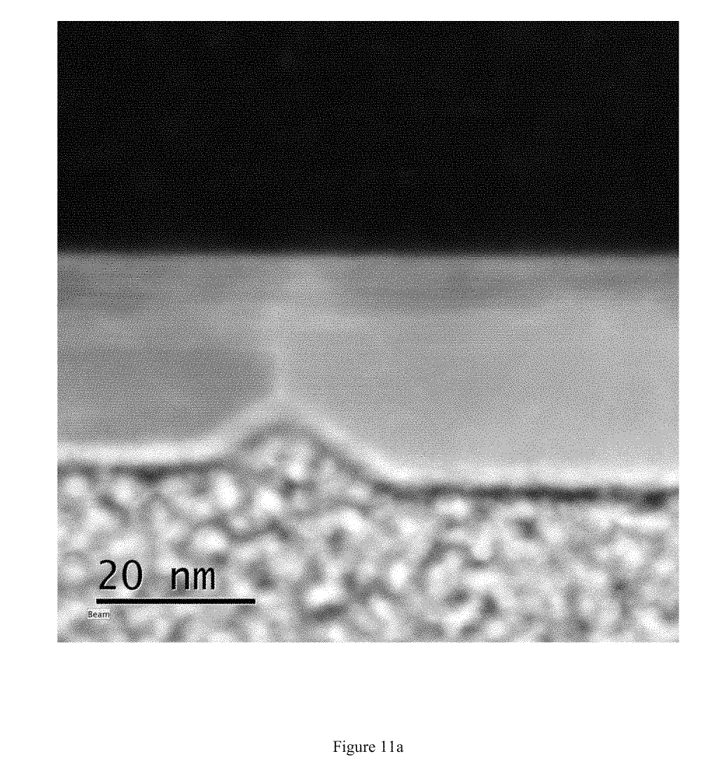

Another aspect of the present invention is providing epitaxial growth of an interface layer that is two-dimensional (2D) in nature and which results in a III-V surface being supported by a Silicon wafer with improved and lower height variation, and preferably being as low as possible. Such a surface can be seen in FIG. 9 (and FIG. 9a), FIG. 10 (and FIG. 10a) and FIG. 11 (and FIG. 11a) in which the height variation is within +/−5 nm. This was obtained by keeping the substrate temperature at 605° C. while growing the group III-V material layers.

FIG. 8 (and FIG. 8a) disclose a drawing of a SEM image of an [111] oriented surface after growth of 5 nm AlAs nucleation layer and 18 nm of GaAs onto an Si(111) substrate. Some indentation lines can be seen across the image, but most of the surface remains at the same level. The SEM image was collected with a 52 degree tilt from the plane normal [111].

FIG. 10 disclose a drawing of a Dark Field TEM cross section image from the sample in FIG. 9 and FIG. 9a. The bottom dark part is the Si substrate, while the middle part is the 5 nm of AlAs nucleation layer plus the 18 nm of GaAs. The top part is amorphous Pt used to protect the sample during microscopy. While several indentations can be seen, they are not very deep and the group III-V material layer remains at about the same thickness across the whole sample surface depicted in the image and the corresponding drawing.

FIG. 11 (and FIG. 11a) disclose an image of a high angle annular Dark Field STEM cross section image of the leftmost indentations in FIG. 9 and corresponding image in FIG. 9a. The top dark part is the Si substrate, while the middle part is the 5 nm of AlAs nucleation layer plus the 18 nm of GaAs. The bottom part is amorphous Pt used to protect the sample during microscopy. A polytype layer can be seen just below the about 10 nm deep indentation. A thickness variation of ca. 5 nm from the leftmost region to the rightmost region can also be seen.

In order to manufacture materials comprising GaAs with good crystal structure, it is normal to increase the temperature to around 670° C. The drawing in FIG. 10 and the image being basis of the drawing depicted in FIG. 10a, and FIG. 11 and the image in FIG. 11a being basis for the drawing in FIG. 11, illustrates that such an increase in temperature gives an annealing effect that increases the height difference. Such an increase in height difference indicates that the epitaxial growth morphology changes into a three-dimensional (3D) growth mode. It also leads to an increased number of areas with different rotations around the [111] axis, indicating that there are at least two growth modes along the (111) plane that have a transition around 605-670° C. In fact, by reducing the temperature even further to 530° C., an even more uniform surface was obtained without visible islands of different rotations. This is in contrast to epitaxial growth on GaAs substrates in which temperatures below 600° C. usually leads to 3D growth and facet formation on the surface.

It has been suggested by the inventors that the temperature range of epitaxial growth according to the present invention is in the range of 400° C. to 650° C.

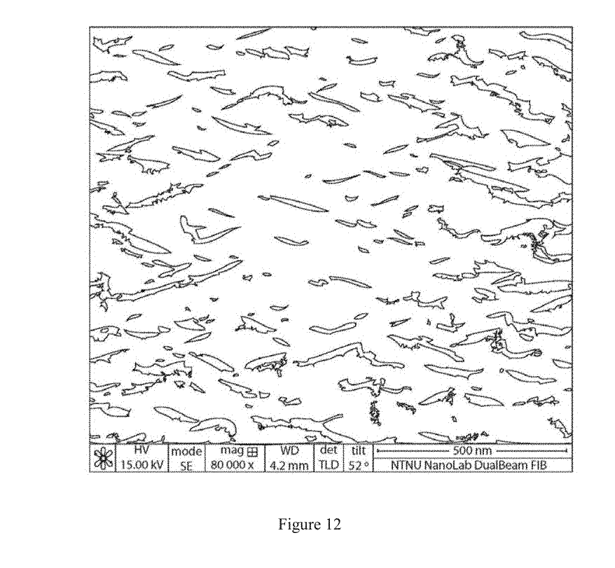

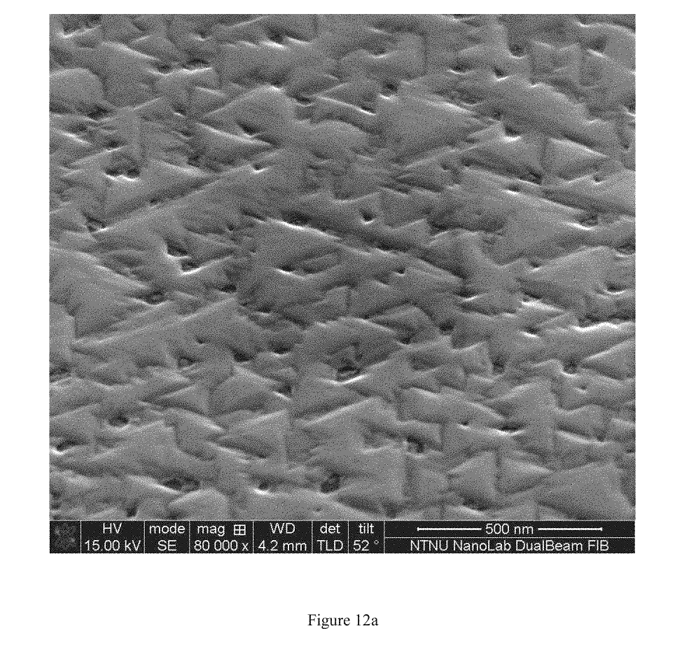

FIG. 12 (and the corresponding image in FIG. 12a) disclose a SEM image of an (111) surface after epitaxial growth of 5 nm AlAs nucleation layer plus 18 nm of GaAs onto a (111) Silicon substrate, with a subsequent annealing step at 670° C. Many indentation lines can be seen across the image, and there are more height variation compared to the image in FIG. 8 and corresponding image in FIG. 8a.

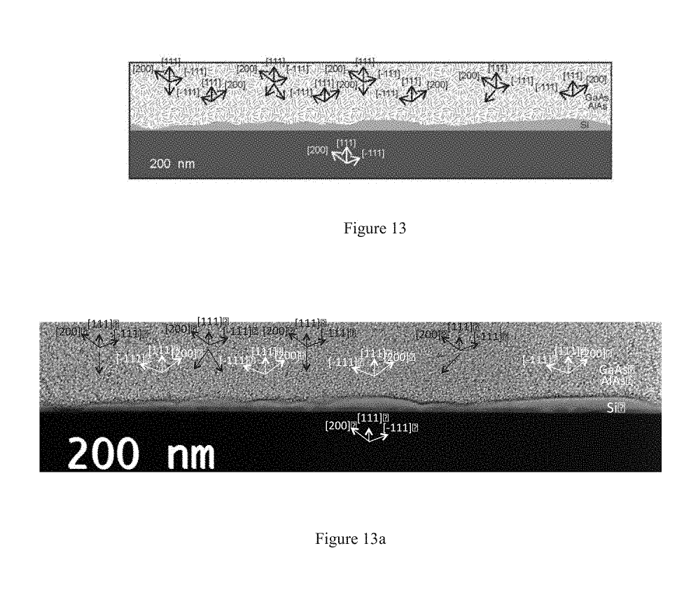

FIG. 13 and corresponding image in FIG. 13a disclose a Dark Field TEM cross section image from the sample in FIG. 11. The top dark part is the Si substrate, while the middle part is the 5 nm of AlAs nucleation layer plus the 18 nm of GaAs.

The bottom part is the amorphous Pt used to protect the sample during microscopy. The III-V layers can be seen to have a high variation in the thickness, all the way to zero thickness in the right hand side of the image.

GaSb is a material with the same crystal structure as GaAs, thus by forming the intermediate GaAsₓSb₁₋ₓ, one can change the material continuously from GaAs to GaSb. In comparison to GaAs, the GaSb material requires a lower temperature to provide crystals of optimal quality (530-550 C) in an epitaxial growth process. By incorporating Sb into the group III-V layers when performing epitaxial growth comprising a Silicon wafer support, the optimal growth temperature of the III-V material is lower. The reason for doing so would be to reduce the number of crystal lattice defects such as interstitials or vacancies. The incorporation of Sb in GaAs has also been seen to suppress 3D growth, facet formation and formation of polytypes. Thus, we can grow GaAsSb at somewhat higher temperature than GaAs without introducing 3D growth. When designing the layers with different amounts of Sb, it is also possible to balance out strain in the group III-V materials that is introduced when reducing (cooling) the temperature after growth, as discussed above.

The material structure being disclosed above can be made into semiconductor devices after doping of the materials. Investigation of the material has indicated that Be-doping leads to p-type doping of the III/V material, while Si-doping leads to n-type doping (for flux ratio of 20 at 670° C.). A problem has been that Si-doping seems to be limited to around 2.5E18 cm-3, while some structures need higher doping. This has been solved by using a GaTe-based doping source to introduce Te-doping into the materials. Thus, Te-doping up to 2E19 cm-3 has been achieved. The Te-doping can easily lead to Te-surfing during growth that prevents Te-incorporation. To limit this effect, the growth temperature can be set below 550° C. for the Te-doped regions of the crystal. Therefore, n-GaAs (n-type GaAs) can be achieved with donor dopant atoms such as Te or alike, and p-GaAs (p-type GaAs) can be achieved with acceptor dopant atoms like Be or alike.

When manufacturing electrical contacts Al can be used as a ohmic contact on p-type Si after annealing, and Pd (50 nm), Ge (100 nm) and Al (200 nm-500 nm) as ohmic contact to n-type GaAs after annealing. The contacts may be annealed at 230° C. to 270° C.

The above method of balancing out or counteracting tensile forces in a material comprising GaAs being supported by a Si wafer is especially beneficial when manufacturing solar cells. A first step of manufacturing a solar cell is polishing of the Si wafer surface. When the Si wafer material has another crystallographic orientation than (111), it is common to use mechanical polishing. However, the possibility to use chemical polishing when using a Si(111) material in the wafer makes it much cheaper and quicker to produce the solar cells. The reference: “Chemical polishing of silicon with anhydrous hydrogen chloride” by Lang, G. A.; Stavish, T. Source: published in RCA Review, v 24, n 4, p 488-498, December, 1963 disclose such a polishing method.

Therefore, manufacturing a solar cell comprising material layers according to the present invention is beneficial. Especially manufacturing of a dual junction solar cell.

It is further within the scope of the present invention to use semiconductor materials from the group of the following materials: Aluminium antimonide (AlSb) (1.6 eV), Aluminium arsenide (AlAs) (2.16 eV, indirect band gap), Aluminium nitride (AlN) (6.28 eV, direct band gap), Aluminium phosphide (AlP) (2.45 eV), Boron nitride (BN), Boron phosphide (BP), Boron arsenide (BAs) (1.5 eV, indirect band gap), Gallium antimonide (GaSb) (0.7 eV), Gallium arsenide (GaAs) (1.43 eV, direct band gap), Gallium nitride (GaN) (3.44 eV, direct band gap), Gallium phosphide (GaP) (2.26 eV, indirect band gap), Indium antimonide (InSb) (0.17 eV, direct band gap), Indium arsenide (InAs) (0.36 eV, direct band gap), Indium nitride (InN) (0.7 eV), Indium phosphide (InP) (1.35 eV, direct band gap), Aluminium gallium arsenide (AlGaAs, AlxGa1-xAs), Indium gallium arsenide (InGaAs, InxGa1-xAs), Indium gallium phosphide (InGaP), Aluminium indium arsenide (AlInAs), Aluminium indium antimonide (AlInSb), Gallium arsenide nitride (GaAsN), Gallium arsenide phosphide (GaAsP), Aluminium gallium nitride (AlGaN), Aluminium gallium phosphide (AlGaP), Indium gallium nitride (InGaN, direct band gap), Indium arsenide antimonide (InAsSb), Indium gallium antimonide (InGaSb), Aluminium gallium indium phosphide (AlGaInP, also InAlGaP, InGaAlP, AlInGaP), Aluminium gallium arsenide phosphide (AlGaAsP), Indium gallium arsenide phosphide (InGaAsP), Aluminium indium arsenide phosphide (AlInAsP), Aluminium gallium arsenide nitride (AlGaAsN), Indium gallium arsenide nitride (InGaAsN), Indium aluminium arsenide nitride (InAlAsN), Gallium arsenide antimonide nitride (GaAsSbN), Gallium indium nitride arsenide antimonide (GaInNAsSb), Gallium indium arsenide antimonide phosphide (GaInAsSbP), Aluminium gallium indium arsenide antimonide (AlGaInAsSb), Aluminium gallium indium nitrid antimonide (AlGaInNSb), Aluminium gallium indium nitrid arsenid (AlGaInNAs), Aluminium gallium indium arsenid phosphide (AlGaInAsP), Aluminium gallium indium antimonide phosphide (AlGaInSbP), Aluminium gallium indium nitride phosphide (AlGaInNP), Aluminium gallium indium nidtride arsenide antimonide (AlGaInNAsSb), Aluminium gallium indium phospide arsenide antimonide (AlGaInPAsSb), Aluminium gallium indium nitride phospide arsenide (AlGaInNPAs), Aluminium gallium indium nitride phospide antimonide (AlGaInNPSb), Cadmium selenide (CdSe) (1.74 eV, direct band gap), Cadmium sulfide (CdS) (2.42 eV, direct band gap), Cadmium telluride (CdTe) (1.49 eV), Magnesium telluride (MgTe) (ca 3-3.5 eV), Magnesium selenide (MgSe) (ca 3.6-4 eV), Magnesium sulfide (MgS) (ca 4.6-5 eV), Zinc oxide (ZnO) (3.37 eV, direct band gap), Zinc selenide (ZnSe) (2.7 eV), Zinc sulfide (ZnS) (3.68 eV), Zinc telluride (ZnTe) (2.25 eV), Cadmium zinc telluride (CdZnTe, CZT), Cadmium zinc selenide (CdZnSe), Cadmium zinc sulfide (CdZnS), Magnesium cadmium telluride (MgCdTe), Magnesium cadmium selenide (MgCdSe), Magnesium zinc telluride (MgZnTe), Magnesium zinc selenide (MgZnSe), Magnesium zinc sulfide (MgZnS), Mercury cadmium telluride (HgCdTe), Mercury zinc telluride (HgZnTe), Mercury zinc selenide (HgZnSe), Cadmium zinc telluride selenide (CdZnTeSe), Cadmium zinc telluride sulfide (CdZnTeS), Cadmium zinc selenide sulfide (CdZnSeS), Magnesium zinc selenide sulfide (MgZnSeS), Magnesium zinc sulfide telluride (MgZnSTe), Magnesium zinc selenide telluride (MgZnSeTe), Magnesium cadmium selenide telluride (MgCdSeTe), Magnesium cadmium selenide sufide (MgCdSeS), Mercury cadmium zinc telluride (HgCdZnTe), Mercury cadmium zinc selenide (HgCdZnSe), Mercury cadmium zinc sulfide (HgCdZnS), Cuprous chloride (CuCl), Lead selenide (PbSe) (0.27 eV, direct band gap), Lead(II) sulfide (PbS) (0.37 eV), Lead telluride (PbTe) (0.29 eV), Tin sulfide (SnS), Tin telluride (SnTe), Lead tin telluride (PbSnTe), Thallium tin telluride (Tl2SnTe5), Thallium germanium telluride (Tl2GeTe5), Bismuth telluride (Bi2Te3), Cadmium phosphide (Cd3P2), Cadmium arsenide (Cd3As2), Cadmium antimonide (Cd3Sb2), Zinc phosphide (Zn3P2), Zinc arsenide (Zn3As2), Zinc antimonide (Zn3Sb2), Zinc arsenide antimonide (Zn3SbAs).

### Abbreviations:

Ga—Gallium
Al—Aluminium
In—Indium
As—Arsenic
Sb—Antimony
Si—Silicon
Te—Tellurium
Be—Beryllium
AlSb—Aluminium antimonide
GaAs—Gallium arsenide
GaSb—Gallium antimonide
AlGaAs—Aluminium gallium arsenide ternary compound semiconductor
AlGaSb—Aluminium gallium antimonide ternary compound semiconductor
AlGaAsSb—Aluminium gallium arsenide antimonide quarternary compound semiconductor
n-GaAs, p-GaAs n- or p-doped GaAs
III-V and other combinations of Roman numerals—Compound semiconductors with elements from (in this case) group III and V of the periodic table of elements.
(111)—a crystallographic orientation
EPD—Etch pit density
TEM—Transmission Electron Microscopy
SEM—Scanning Electron Microscopy
STEM Scanning Transmission Electron Microscopy
XRD—X-ray diffraction
FWHM—Full width at half maximum

1. A method of counteracting residual strain in semiconductor materials comprising group III-V materials in layers deposited in an epitaxial growth process on a Si(111) wafer, the method comprises steps of:
using an arsenic source during the epitaxial growth process, and
adding a step in the epitaxial growth process constituting a first layer comprising a group III-V material combination providing a specific first lattice constant, followed by adding a further step in the epitaxial growth process constituting a second layer comprising a group III-V material combination providing a specific second lattice constant,
wherein the second lattice constant is less than the first lattice constant,
wherein the arsenic concentration varies with a concentration increase of more than 5 at % from the start of the first layer to the end of the second layer.

2. The method according to claim 1, wherein the first lattice constant and the second lattice constant is selected according to a target band gap of the semiconductor materials being the result of the epitaxial growth process.

3. The method according to claim 1, wherein the first layer is a nucleation layer.

4. The method according to claim 3, wherein the first layer is constituted by AlAs.

5. The method according to claim 1, wherein the first layer is constituted by AlAsₓSb₁₋ₓ, wherein 0<x<1, wherein x is selected to provide a material composition providing the first specific lattice constant.

6. The method according to claim 1, wherein the first layer is constituted by InAsₓSb₁₋ₓ, wherein 0<x<1, wherein x is selected to provide a material composition providing the first specific lattice constant.

7. The method according to claim 1, wherein the first layer is constituted by Al_{1-y}In_{y}AsₓSb₁₋ₓi, wherein 0<x<1 and 0<y<1, wherein x and y is selected to provide a material composition providing the first specific lattice constant.

8. The method according to claim 1, wherein the second layer is constituted by AlAsₓSb₁₋ₓ, wherein 0<x<1, wherein x is selected to provide a material composition providing the second specific lattice constant.

9. The method according to claim 1, wherein the second layer is constituted by Al_{y}Ga_{1-y}AsₓSb₁₋ₓ, wherein 0<x<1 and 0<y<1, wherein x and y is selected to provide a material composition providing the second specific lattice constant.

10. The method according to claim 1, wherein the second layer is constituted by Al_{y}Ga_{1-y-z}In_{z}AsₓSb₁₋ₓ, wherein 0<x<1, and 0<y<1, and 0<z<1, and y+z=<1, wherein x, y and z is selected to provide a material composition providing the second specific lattice constant.

11. The method according to claim 1, wherein the method of epitaxial growth comprises using a temperature in an interval of 400° C. to 650° C.

12. The method according to claim 1, wherein the method of epitaxial growth comprises using a temperature in an interval of 530° C. to 550° C.

13. The method according to claim 1, wherein the semiconductor materials are selected from a group of materials comprising:
Aluminium antimonide (AlSb) (1.6 eV),
Aluminium arsenide (AlAs) (2.16 eV, indirect band gap),
Aluminium nitride (AlN) (6.28 eV, direct band gap),
Aluminium phosphide (AlP) (2.45 eV),
Boron nitride (BN),
Boron phosphide (BP),
Boron arsenide (BAs) (1.5 eV, indirect band gap),
Gallium antimonide (GaSb) (0.7 eV),
Gallium arsenide (GaAs) (1.43 eV, direct band gap),
Gallium nitride (GaN) (3.44 eV, direct band gap),
Gallium phosphide (GaP) (2.26 eV, indirect band gap),
Indium antimonide (InSb) (0.17 eV, direct band gap),
Indium arsenide (InAs) (0.36 eV, direct band gap),
Indium nitride (InN) (0.7 eV),
Indium phosphide (InP) (1.35 eV, direct band gap),
Aluminium gallium arsenide (AlGaAs, AlxGa1-xAs),
Indium gallium arsenide (InGaAs, InxGa1-xAs),
Indium gallium phosphide (InGaP),
Aluminium indium arsenide (AlInAs),
Aluminium indium antimonide (AlInSb),
Gallium arsenide nitride (GaAsN),
Gallium arsenide phosphide (GaAsP),
Aluminium gallium nitride (AlGaN)
Aluminium gallium phosphide (AlGaP),
Indium gallium nitride (InGaN, direct band gap),
Indium arsenide antimonide (InAsSb),
Indium gallium antimonide (InGaSb),
Aluminium gallium indium phosphide (AlGaInP, also InAlGaP, InGaAlP, AlInGaP),
Aluminium gallium arsenide phosphide (AlGaAsP),
Indium gallium arsenide phosphide (InGaAsP),
Aluminium indium arsenide phosphide (AlInAsP),
Aluminium gallium arsenide nitride (AlGaAsN),
Indium gallium arsenide nitride (InGaAsN),
Indium aluminium arsenide nitride (InAlAsN),
Gallium arsenide antimonide nitride (GaAsSbN),
Gallium indium nitride arsenide antimonide (GaInNAsSb),
Gallium indium arsenide antimonide phosphide (GaInAsSbP)
Aluminium gallium indium arsenide antimonide (AlGaInAsSb),
Aluminium gallium indium nitrid antimonide (AlGaInNSb),
Aluminium gallium indium nitrid arsenid (AlGaInNAs),
Aluminium gallium indium arsenid phosphide (AlGaInAsP),
Aluminium gallium indium antimonide phosphide (AlGaInSbP),
Aluminium gallium indium nitride phosphide (AlGaInNP),
Aluminium gallium indium nidtride arsenide antimonide (AlGaInNAsSb),
Aluminium gallium indium phospide arsenide antimonide (AlGaInPAsSb),
Aluminium gallium indium nitride phospide arsenide (AlGaInNPAs),
Aluminium gallium indium nitride phospide antimonide (AlGaInNPSb),
Cadmium selenide (CdSe) (1.74 eV, direct band gap),
Cadmium sulfide (CdS) (2.42 eV, direct band gap),
Cadmium telluride (CdTe) (1.49 eV),
Magnesium telluride (MgTe) (ca 3-3.5 eV),
Magnesium selenide (MgSe) (ca 3.6-4 eV),
Magnesium sulfide (MgS) (ca 4.6-5 eV),
Zinc oxide (ZnO) (3.37 eV, direct band gap),
Zinc selenide (ZnSe) (2.7 eV),
Zinc sulfide (ZnS) (3.68 eV),
Zinc telluride (ZnTe) (2.25 eV),
Cadmium zinc telluride (CdZnTe, CZT),
Cadmium zinc selenide (CdZnSe),
Cadmium zinc sulfide (CdZnS),
Magnesium cadmium telluride (MgCdTe),
Magnesium cadmium selenide (MgCdSe),
Magnesium zinc telluride (MgZnTe),
Magnesium zinc selenide (MgZnSe),
Magnesium zinc sulfide (MgZnS),
Mercury cadmium telluride (HgCdTe),
Mercury zinc telluride (HgZnTe),
Mercury zinc selenide (HgZnSe),
Cadmium zinc telluride selenide (CdZnTeSe),
Cadmium zinc telluride sulfide (CdZnTeS),
Cadmium zinc selenide sulfide (CdZnSeS),
Magnesium zinc selenide sulfide (MgZnSeS),
Magnesium zinc sulfide telluride (MgZnSTe),
Magnesium zinc selenide telluride (MgZnSeTe),
Magnesium cadmium selenide telluride (MgCdSeTe),
Magnesium cadmium selenide sufide (MgCdSeS),
Mercury cadmium zinc telluride (HgCdZnTe),
Mercury cadmium zinc selenide (HgCdZnSe),
Mercury cadmium zinc sulfide (HgCdZnS),
Cuprous chloride (CuCl),
Lead selenide (PbSe) (0.27 eV, direct band gap),
Lead(II) sulfide (PbS) (0.37 eV),
Lead telluride (PbTe) (0.29 eV),
Tin sulfide (SnS),
Tin telluride (SnTe),
Lead tin telluride (PbSnTe),
Thallium tin telluride (Tl2SnTe5),
Thallium germanium telluride (Tl2GeTe5),
Bismuth telluride (Bi2Te3),
Cadmium phosphide (Cd3P2),
Cadmium arsenide (Cd3As2),
Cadmium antimonide (Cd3Sb2),
Zinc phosphide (Zn3P2),
Zinc arsenide (Zn3As2),
Zinc antimonide (Zn3Sb2),
Zinc arsenide antimonide (Zn3SbAs).

14. A solar cell comprising a first material layer and a second material layer according to claim 1.

15. The solar cell according to claim 14 wherein the solar cell comprises a dual junction solar cell.
